(19) United States
(12) Patent Application Publication
(10) Pub. No.: US 2012/0206829 A1
(43) Pub. Date: Aug. 16, 2012

(54) METHOD OF TESTING MAGNETIC RECORDING MEDIUM

(75) Inventor: Shuji Hatada, Ichihara-shi (JP)

(73) Assignee: SHOWA DENKO K.K., Minato-ku, Tokyo (JP)

(21) Appl. No.: 13/502,828

(22) PCT Filed: Oct. 21, 2010
(86) PCT No.: PCT/JP2010/068589

§ 371 Date: Apr. 19, 2012

(30) Foreign Application Priority Data
Oct. 29, 2009 (JP) 2009-249136

(51) Int. Cl. G11B 27/36; C23C 14/34; G11B 5/851

(52) U.S. Cl. 360/31; 204/192.2; G9B/27.052; G9B/5.304

(57) ABSTRACT

Disclosed is a method of testing a magnetic recording medium including a magnetically isolated magnetic recording pattern (41a) on a non-magnetic substrate. The method includes: a first signal writing step of writing a first signal (6) with a width less than a track width at a plurality of measurement positions (5) on the magnetic recording pattern (41a) using a writing head; a first signal reading step of reading the first signal (6) using the reading head to obtain a plurality of first read signals corresponding to the measurement positions (5); and an analysis step of analyzing magnetic characteristics of the magnetic recording pattern (41a) using the plurality of first read signals obtained in the first signal reading step. The test method is suitable for testing the magnetic characteristic distribution of a discrete track medium and is capable of testing the magnetic characteristic distribution of a magnetic recording medium with high accuracy.

### TECHNICAL FIELD

The present invention relates to a method of testing a magnetic recording medium used in, for example, a hard disk device and more particularly, to a method of testing a magnetic recording medium capable of testing the magnetic characteristic distribution of a discrete track medium with high accuracy.

### BACKGROUND ART

In recent years, the application range of a magnetic recording device; such as a hard disk device, has been significantly widened, the importance of the magnetic recording device has increased, and the recording density of magnetic recording media used in the magnetic recording device has been significantly improved.

As a technique for increasing the track density, there is an attempt to form concave and convex portions on the surface of a recording medium along the tracks and physically or magnetically isolate the recording tracks, thereby increasing the track density. This technique is called a discrete track method and the magnetic recording medium manufactured by the discrete track method is called a discrete track medium.

As an example of the discrete track medium, a magnetic recording medium has been proposed in which a soft magnetic layer and a ferromagnetic layer are formed on a non-magnetic substrate including a plurality of convex portions and a plurality of concave portions surrounding the convex portions, concave and convex portions corresponding to the shape of the non-magnetic substrate are formed on the soft magnetic layer and the ferromagnetic layer, and only the magnetically-isolated convex portions of the ferromagnetic layer are used as a recording region (for example, see Patent Document 1).

As a method of testing the shape of the magnetically isolated magnetic recording pattern forming the discrete track medium, a method has been proposed which observes a cross-section using a transmission electron microscope (TEM).

### CITATION LIST

### Patent Document

[Patent Document 1] JP-A-2004-164692

### SUMMARY OF INVENTION

### Technical Problem

However, when the transmission electron microscope (TEM) is used to observe the cross section, thereby testing the shape of the magnetically isolated magnetic recording pattern, it takes a lot of time and effort to perform the test.

In addition, even when the transmission electron microscope (TEM) is used to observe the cross section, it is difficult to accurately know the magnetic characteristic distribution of the discrete track medium and thus measure the magnetic shape of the magnetically isolated magnetic recording pattern, the amount of magnetism remaining in the isolation region which magnetically isolates adjacent recording regions, and the magnetic difference between the recording region and the isolation region. Therefore, a test method capable of testing in detail the magnetic characteristic distribution of the discrete track medium with high accuracy is needed.

The invention has been made in view of the above-mentioned problems and an object of the invention is to provide a method of testing a magnetic recording medium which is suitable for testing the magnetic characteristic distribution of a discrete track medium and is capable of easily testing the magnetic characteristic distribution of a magnetic recording medium with high accuracy.

### Solution to Problem

The inventors have conducted studies as follows in order to achieve the object.

That is, the inventors found a technique which wrote a plurality of first signals with a width less than a track width to a magnetic recording pattern using a writing head of a magnetic head, read the first signals using a reading head of the magnetic head to obtain a plurality of first read signals, and analyzed the magnetic characteristics of the magnetic recording pattern using the plurality of first read signals, which made it possible to accurately test the magnetic characteristic distribution of the magnetic recording medium and thus know in detail the magnetic shape of a magnetically isolated magnetic recording pattern of a discrete track medium, the amount of magnetism remaining in an isolation region which magnetically isolated adjacent recording regions, and the magnetic difference between a recording region and the isolation region, thereby achieving the invention.

That is, the invention has the following structure.

According to a first aspect of the invention, there is provided a method of testing a magnetic recording medium including a magnetically isolated magnetic recording pattern on a non-magnetic substrate. The method includes: a first signal writing step of writing a first signal with a width less than a track width at a plurality of measurement positions on the magnetic recording pattern using a writing head; a first signal reading step of reading the first signal using a reading head to obtain a plurality of first read signals corresponding to the measurement positions; and an analysis step of analyzing magnetic characteristics of the magnetic recording pattern using the plurality of first read signals obtained in the first signal reading step.

According to a second aspect of the invention, in the method of testing a magnetic recording medium according to the first aspect, the first signal writing step may include: a second signal writing step of writing a second signal with a width greater than that of the first signal to the magnetic recording pattern using the writing head; and an erasing signal writing step of writing an erasing signal for erasing the second signal to one side or both sides of the edge of the second signal in a track width direction using the writing head, thereby generating the first signal.

According to a third aspect of the invention, in the method of testing a magnetic recording medium according to the first or second aspect, the magnetic recording pattern may include servo information. In the first signal writing step and the first signal reading step, the reading head may read the servo information and the magnetic head including the reading head and the writing head may be located at a predetermined position on the magnetic recording pattern.

According to a fourth aspect of the invention, in the method of testing a magnetic recording medium according to any one of the first to third aspects, the plurality of measurement positions may be arranged on the magnetic recording pattern at intervals less than the track width in a radial direction of the non-magnetic substrate.

According to a fifth aspect of the invention, in the method of testing a magnetic recording medium according to any one of the first to fourth aspects, in the first signal reading step, the center of the reading head in the radial direction of the non-magnetic substrate may be aligned with the center of the measurement position in the radial direction of the non-magnetic substrate, and the reading head may read the first signal.

### Advantageous Effects of Invention

A method of testing a magnetic recording medium according to the invention includes a first signal writing step of writing a first signal with a width less than a track width at a plurality of measurement positions on the magnetic recording pattern using a writing head, a first signal reading step of reading the first signal using the reading head to obtain a plurality of first read signals corresponding to the measurement positions, and an analysis step of analyzing magnetic characteristics of the magnetic recording pattern using the plurality of first read signals obtained in the first signal reading step. Therefore, it is possible to test the magnetic characteristic distribution of the magnetic recording pattern with high accuracy.

The method of testing a magnetic recording medium according to the invention can test the magnetic characteristic distribution of the magnetic recording pattern at a high speed. Therefore, the method of testing a magnetic recording medium according to the invention can be suitable for testing the entire magnetic recording medium.

### BRIEF DESCRIPTION OF DRAWINGS

FIG. 1A is a diagram schematically illustrating the entire magnetic recording medium tested by a magnetic recording medium test method according to the invention.

FIG. 1B is an enlarged view schematically illustrating only a rectangular portion of the magnetic recording medium in FIG. 1A.

FIG. 2 is a cross-sectional view illustrating the cross-sectional structure of the magnetic recording medium shown in FIG. 1A and is also an enlarged view illustrating a portion of the magnetic recording medium, as viewed in the radial direction.

FIG. 3 is a perspective view schematically illustrating a hard disk drive, which is an example of a test device which can be used in the magnetic recording medium test method.

FIG. 4 is a diagram illustrating a method of testing the magnetic characteristics of a magnetic recording pattern of the magnetic recording medium shown in FIG. 1B and is also an enlarged view schematically illustrating a state in which first signals are written at a plurality of measurement positions on the magnetic recording pattern.

FIG. 5 is a diagram illustrating an example of the analysis result of the magnetic characteristics of the magnetic recording pattern and is a graph illustrating the relationship between the amplitude intensity of a first read signal and the measurement position for obtaining the first read signal.

FIG. 6 is a graph illustrating the distribution of the output intensity of a second signal in the vicinity of the center in the radial direction and is also a graph illustrating the output intensity of the second signal remaining after an erasing signal is written when the output intensity of the second signal without an erasing signal written thereto is 100%.

FIG. 7 is a graph illustrating the distribution of the output intensity in the width direction of the track in the range of ±50 nm from the center in the radial direction and is also a graph illustrating the output intensity when the output intensity at the center of the track in the radial direction in the distribution (a line with a physical shape in FIG. 7) of the output intensity, which is a target value in manufacturing, is 100%.

### DESCRIPTION OF EMBODIMENTS

Hereinafter, a magnetic recording medium test method according to the invention will be described in detail with reference to the accompanying drawings. In the drawings referred to in the following description, in some cases, for example, the size, thickness, and dimensions of each component shown in the drawings are different from the actual size, thickness, and dimensions of each component in a magnetic recording medium and a magnetic recording/reproducing apparatus.

### <Magnetic Recording Medium>

First, an example of a magnetic recording medium, which is an object to be tested by the magnetic recording medium test method according to the invention, will be described.

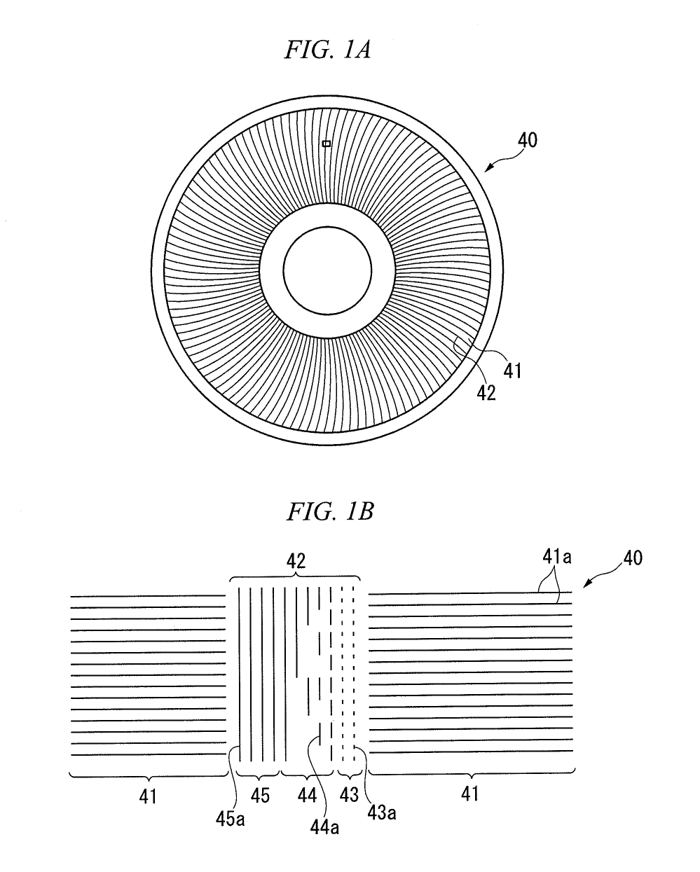

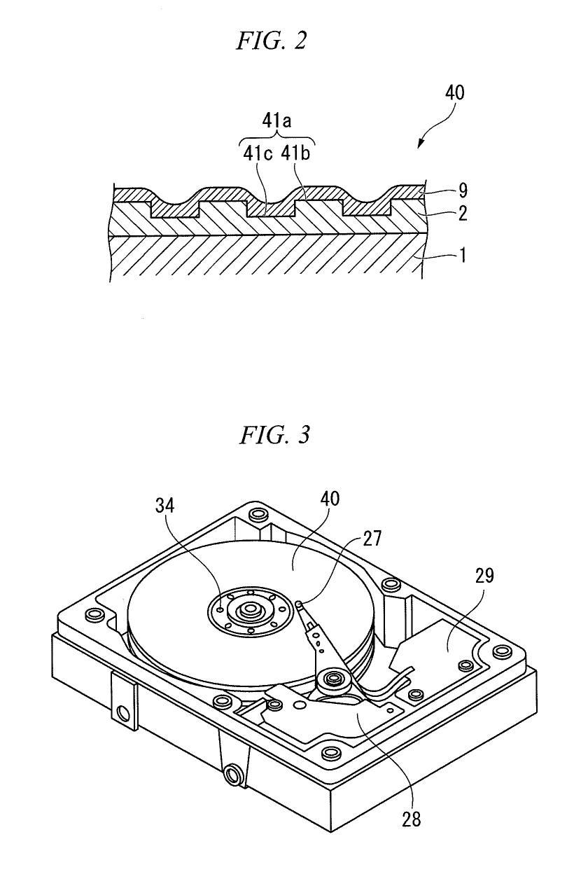

FIG. 1 is a plan view illustrating an example of the magnetic recording medium tested by the magnetic recording medium test method according to the invention. Specifically, FIG. 1A is a diagram schematically illustrating the overall structure of the magnetic recording medium and FIG. 1B is an enlarged view schematically illustrating only a rectangular portion of the magnetic recording medium in FIG. 1A. FIG. 2 is a cross-sectional view illustrating the cross-sectional structure of the magnetic recording medium shown in FIG. 1A and is also an enlarged view illustrating a portion of the magnetic recording medium as viewed from the radial direction. In FIG. 2, for ease of explanation, only a substrate, a magnetic layer, and a protective layer are shown.

A magnetic recording medium 40 according to this embodiment is a discrete magnetic recording medium and includes data regions 41 and servo information regions 42 formed on the surface of a substrate 1, which is a disk-shaped non-magnetic substrate, as shown in FIGS. 1A and 1B. In FIG. 1A, a region which is represented by a line which radially extends from the center corresponds to the servo information region 42 and a region between the lines which radially extend corresponds to the data region 41.

As shown in FIGS. 1B and 2, a magnetic recording pattern 41a, which is a magnetically isolated magnetic layer 2, is formed in the data region 41. The “magnetically isolated” magnetic layer 2 may include a structure in which at least the surface of the magnetic layer 2 is magnetically isolated and a structure in which the bottom of the magnetic layer 2 is not magnetically isolated.

The magnetic recording pattern 41a forms a magnetic recording track. As shown in FIG. 1B, the magnetic recording pattern 41a is regularly formed in a concentric shape with respect to the rotation center of the disk-shaped magnetic recording medium 40. As shown in FIG. 2, the magnetic recording pattern 41a includes a convex portion 41b serving as a recording region and a concave portion 41c serving as an isolation region which magnetically isolates adjacent recording regions. The concave portion 41c is demagnetized by changing the magnetic characteristics of the magnetic layer 2.

As shown in FIG. 1B, the servo information region 42 includes a burst information region 43, an address information region 44, and a preamble information region 45.

The burst pattern 43a serving as burst information for positioning a magnetic head at the center of the magnetic recording track is formed in the burst information region 43. The burst pattern 43a is a magnetic layer forming the burst information region 43 and has a fine dotted pattern provided between adjacent magnetic recording tracks.

In addition, an address pattern 44a serving as address information including track information indicating the address of the data region 41 and sector information is formed in the address information region 44. The address pattern 44a is a magnetic layer forming the address information region 44 and has an irregular linear shape which extends in a direction perpendicular to the data recording pattern 41a.

A preamble pattern 45a serving as preamble information used to identify the position moved from the data region 41 to the servo information region 42 in the magnetic recording track is formed in the preamble information region 45. The preamble pattern 45a is a magnetic layer forming the preamble information region 45 and has a linear shape with the same length which extends in a direction perpendicular to the data recording pattern 41a.

In this embodiment, a plurality of data regions 41 provided on the non-magnetic substrate 1 are positioned by servo information including the burst information, the address information, and the preamble information included in the servo information region 42. In the magnetic recording medium 40 according to this embodiment, the magnetic head (not shown) which moves on the surface of the magnetic recording medium 40 in the circumferential direction can read the preamble information, address information, and burst information of the corresponding data region 41 from the servo information region 42, adjust the position of the magnetic head relative to the magnetic recording track position of the magnetic recording pattern 41a, and read or write information.

As shown in FIG. 2, in the magnetic recording medium 40 shown in FIG. 1A, the magnetic layer 2 is formed on the non-magnetic substrate 1, a protective layer 9 is formed on the magnetic layer 2, and a lubricant layer (not shown in FIG. 2) is formed on the protective layer 9.

In this embodiment, the magnetic recording medium 40 including the protective layer 9 and the lubricant layer is described as an example, but the protective layer 9 and the lubricant layer may not be provided.

In this embodiment, the discrete magnetic recording medium 40 including the convex portion 41b and the concave portion 41c shown in FIGS. 1A and 2 are given as an example of the object tested by the magnetic recording medium test method according to the invention. However, the magnetic recording medium tested by the magnetic recording medium test method according to the invention is not limited to the magnetic recording medium 40 shown in FIGS. 1A and 2, but any magnetic recording medium may be used as long as it includes the magnetically isolated magnetic recording pattern. Specifically, in the magnetic recording medium tested by the magnetic recording medium test method according to the invention, the isolation region which magnetically isolates the adjacent recording regions may not be the concave portion.

### <Magnetic Recording Medium Test Device>

Next, an example of a device for testing the magnetic characteristics of the magnetic recording pattern 41a of the magnetic recording medium 40 shown in FIG. 1A will be described.

For example, a magnetic recording/reproducing device, such as a hard disk drive (HDD) shown in FIG. 3, is given as an example of a test device which can be used in the magnetic recording medium test method according to the invention.

The hard disk drive shown in FIG. 3 includes the discrete magnetic recording medium 40 shown in FIG. 1A, a medium driving unit 34 that drives the magnetic recording medium 40 in a recording direction, a magnetic head 27 including a reading head and a writing head, a head driving unit 28 that moves the magnetic head 27 relative to the magnetic recording medium 40, and a recording/reproducing signal system 29 (recording/reproducing signal processing means) that inputs a signal to the magnetic head 27 and reproduces an output signal from the magnetic head 27.

The test device which can be used in the magnetic recording medium test method according to this embodiment is not limited to the hard disk drive shown in FIG. 3. For example, other magnetic recording/reproducing devices or rotary devices (spin stands) for evaluating the recording/reproducing performances may be used.

### <Magnetic Recording Medium Test Method>

Next, a method of testing the magnetic characteristics of the magnetic recording pattern 41a of the magnetic recording medium 40 shown in FIG. 1B using the hard disk drive shown in FIG. 3 will be described.

### (First Signal Writing Process)

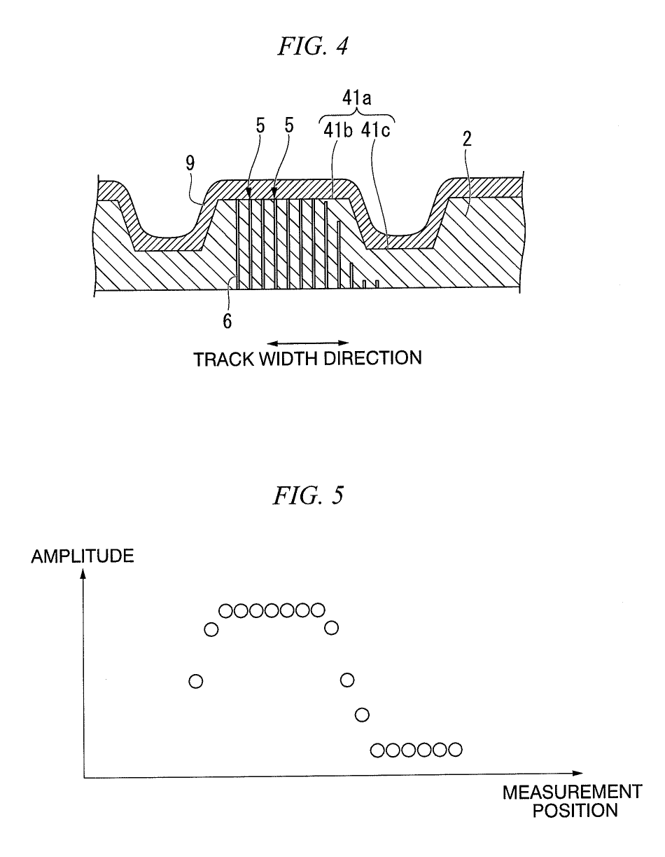

First, as shown in FIG. 4, the writing head of the magnetic head 27 (not shown in FIG. 4) is used to write a first signal 6 with a width less than a track width at a plurality of measurement positions 5 on the magnetic recording pattern 41a.

In this embodiment, when the first signal 6 is written at each of the plurality of measurement positions 5, first, the center of the writing head is located at each measurement position 5. In order to locate the magnetic head at each measurement position 5 where the first signal 6 is written, it is preferable to use a method of directing the reading head of the magnetic head to read the servo information of the magnetic recording medium 40 and locating the magnetic head at a predetermined position on the magnetic recording pattern 41a. In this way, it is possible to easily and accurately locate the magnetic head at each measurement position 5 on the magnetic recording pattern 41a.

It is preferable that the plurality of measurement positions 5 be arranged on the magnetic recording pattern 41a at regular intervals less than the track width in the radial direction of the non-magnetic substrate 1, as shown in FIG. 4. When the plurality of measurement positions 5 are arranged on the magnetic recording pattern at regular intervals less than the track width in the radial direction of the non-magnetic substrate 1, it is possible to test in detail the magnetic characteristic distribution of the magnetic recording pattern 41a in the radial direction of the non-magnetic substrate 1 with high accuracy. Therefore, it is possible to accurately test in detail the magnetic characteristic distribution of the magnetic recording pattern 41a forming the magnetic recording tracks which are regularly formed in a concentric shape with respect to the rotation center of the disk-shaped magnetic recording medium 40.

It is preferable that the first signal writing process include a second signal writing process of writing a second signal with a width greater than that of the first signal 6 to the magnetic recording pattern 41a using the writing head and an erasing signal writing process of writing an erasing signal for erasing the second signal to one side or both sides of the edge of the second signal in the track width direction using the writing head, thereby generating the first signal 6. In the method in which the first signal writing process including the second signal writing process and the erasing signal writing process, it is possible to easily write the first signal 6 with a width less than the track width at the measurement position 5 on the magnetic recording pattern 41a.

It is preferable that the first signal writing process write the first signal 6 with the writing head, using a method of writing two or more kinds of signals with different frequencies at different positions in the track width direction with a width less than the track width.

Specifically, for example, the following method may be used: a medium-frequency signal is written as the second signal in the second signal writing process of the first signal writing process including the second signal writing process and the erasing signal writing; and a high-frequency signal is written as the erasing signal in the erasing signal writing process. In the first signal writing process, the high-frequency signal is written as the erasing signal to generate the first signal 6 including the medium-frequency signal, which is the remaining second signal. In the first signal writing process, since two or more kinds of signals with different frequencies are written at different positions in the track width direction with a width less than the track width, it is possible to easily write the first signals with a width less than the track width at the measurement positions on the magnetic recording pattern 41a. At that time, the magnetic head reads the servo information provided in the magnetic recording medium 40. In this way, the magnetic head can be located at an arbitrary position of the track. Therefore, the magnetic head can be located at, each measurement position 5.

The width of the first signal 6 may be less than the track width. It is preferable that the output of the first read signal be in the range of 10% to 30% of the second signal output, which is the writing width of the head. When the width of the first signal 6 is less than the above-mentioned range, the output of the first read signal obtained in the first signal reading process, which will be described below, is too small and the accuracy of the test is likely to be insufficient. When the width of the first signal 6 is more the above-mentioned range, it is difficult to write the first signal 6 in a test target region with high density and thus sufficiently increase the density of the first read signal obtained in the first signal reading process, which will be described below.

### (First Signal Reading Process)

Then, the reading head of the magnetic head reads the first signals, thereby obtaining a plurality of first read signals corresponding to the measurement positions 5. In this embodiment, when the reading head reads the first signals 6, the magnetic head is located at each measurement position 5.

In order to locate the magnetic head at each measurement position 5 where the first signal 6 is written, it is preferable to use a method of reading the servo information of the magnetic recording medium 40 using the reading head and locating the magnetic head at a predetermined position on the magnetic recording pattern 41a. In this way, it is possible to easily and accurately locate the magnetic head at each measurement position 5 on the magnetic recording pattern 41a.

In the first signal reading process, it is preferable to align the center of the reading head in the radial direction with the center of the measurement position 5 on the magnetic recording medium 40 in the radial direction and read the first signal 6 using the reading head. It is considered that the sensitivity of the reading head is distributed (varies) in the track width direction, which is the radial direction of the non-magnetic substrate 1. When the reading head is located at the measurement position 5 such that the center of the reading head is aligned with the center of the magnetic recording medium 40 in the radial direction, it is possible to reduce a variation in the test result due to the sensitivity of the reading head. Therefore, it is possible to test the magnetic characteristics of the magnetic recording pattern with high accuracy.

When the erasing signals with different frequencies are written to one side or both sides of the edge in the track width direction to obtain the first signal 6, the reading head can read only a specific frequency component forming the first signal 6 in the first signal reading process, thereby obtaining the first read signal corresponding to the measurement position 5.

The sequence for obtaining the plurality of first read signals in the magnetic recording medium test method according to the invention is not particularly limited. However, it is preferable to perform the first signal reading process of reading the first signal using the reading head, thereby obtaining one first read signal corresponding to one measurement position whenever the first signal writing process of writing the first signal at one of the plurality of measurement positions 5 on the magnetic recording pattern 41a is performed. In this case, the first signal writing process and the first signal reading process are alternately performed at the plurality of measurement positions 5 to obtain a plurality of first read signals corresponding to the plurality of measurement positions 5. In this way, it is possible to test the magnetic characteristics of the magnetic recording pattern.

In the magnetic recording medium test method according to the invention, as another sequence for obtaining the plurality of first read signals, for example, the first signal writing process of writing the first signal at one of the plurality of measurement positions 5 on the magnetic recording pattern 41a may be performed plural times to write the first signals at the plurality of measurement positions, and the first signal reading process of obtaining one first read signal corresponding to one measurement position may be performed plural times to obtain a plurality of first read signals corresponding to the plurality of measurement positions.

In the magnetic recording medium test method according to the invention; the positions or number of measurement positions 5 for obtaining a plurality of first read signals are not particularly limited, but may be determined by a test target region.

For example, the plurality of measurement positions 5 may be arranged in one sector, or the measurement positions 5 may be arranged in a plurality of sectors. In addition, the plurality of measurement positions 5 may be arranged in one track, the measurement positions 5 may be arranged so as to be dispersed in a plurality of tracks, or the measurement positions 5 may be arranged in all the tracks. When all of the plurality of measurement positions 5 are arranged in one sector, only one servo information item is used to align the writing head with the measurement position in the first signal writing process. Therefore, it is possible to align the writing head with the measurement position in the first signal writing process with high accuracy, as compared to the structure in which the measurement positions 5 are arranged in a plurality of sectors.

### (Analysis Process)

Then, the magnetic characteristics of the magnetic recording pattern 41a are analyzed using the plurality of first read signals obtained in the first signal reading process. As a method of analyzing the magnetic characteristics of the magnetic recording pattern 41a, for example, a method may be used which analyzes the relationship between amplitude intensity, which is an output from the first read signal, and the measurement position for obtaining the first read signal.

FIG. 5 is a diagram illustrating an example of the analysis result of the magnetic characteristics of the magnetic recording pattern 41a and is a graph illustrating the relationship between the amplitude intensity of the first read signal and the measurement position for obtaining the first read signal.

For example, the analysis result shown in FIG. 5 is obtained when a plurality of measurement positions 5 are arranged on the magnetic recording pattern 41a at intervals less than the track width in the radial direction of the non-magnetic substrate 1. As shown in FIG. 5, when the magnetic characteristics of the magnetic recording pattern 41a are analyzed, it is possible to detect in detail the magnetic characteristic distribution of the magnetic recording pattern 41a with high accuracy. In addition, as shown in FIG. 5, it is possible to detect in detail the magnetic shape of the magnetically isolated magnetic recording pattern 41a, the magnetic difference between the convex portion 41b, which is a recording region, and the concave portion 41c, which is an isolation region, and the amount of magnetism remaining in the concave portion 41c with ease, from the test result of the magnetic recording medium according to this embodiment.

The magnetic recording medium test method according to the invention is not limited to the above-described embodiment.

For example, in the first signal writing process, any method may be used as long as it can write the first signal 6 with a width less than the track width at a plurality of measurement positions 5 on the magnetic recording pattern 41a using the writing head of the magnetic head, and the first signal writing process is not limited to the method including the second signal writing process and the erasing signal writing process. In addition, the frequencies of the first signal, the second signal, and the erasing signal are not limited to the above-mentioned example.

When the reading head of the magnetic head reads the first signals 6 to obtain a plurality of first read signals corresponding to the measurement positions 5, in order to test the magnetic characteristics of the magnetic recording pattern 41a with high accuracy, for example, a filter that outputs only a specific frequency component may be used to remove signals other than the output from the first read signals obtained in the first signal reading process.

The analysis result of the magnetic characteristics of the magnetic recording pattern is not limited to the graph shown in FIG. 5. For example, a plan view using a contour line may be used and the analysis result may be determined by the purpose of the test, the number of measurement positions, and a test target region, but is not particularly limited.

### EXAMPLES

Next, examples will be described in order to clarify the effect of the invention. The invention is not limited to the following examples, but the examples may be appropriately changed without departing from the scope and spirit of the invention.

### (Manufacture of Magnetic Recording Medium)

A magnetic recording medium used for test was manufactured as follows. A vacuum chamber in which a HD glass substrate was set was evacuated to a pressure of 1.0×10⁻⁵ Pa or less in advance. The glass substrate used in this example was made of a crystallized glass having Li₂Si₂O₅, Al₂O₃—K₂O, Al₂O₃—K₂O, MgO—P₂O₅, and Sb₂O₃—ZnO as components, and had an outside diameter of 65 mm, an inside diameter of 20 mm, and an average surface roughness (Ra) of 2 angstroms.

A DC sputtering method was used to laminate FeCoB serving as a soft magnetic layer, Ru serving as an intermediate layer, a 70Co-5Cr-15Pt-10SiO₂ alloy serving as a magnetic layer, and CrTi serving as a metal protective layer on the glass substrate, and a sputtering method was used to laminate C serving as a mask layer thereon.

The thickness of each layer was as follows. The thickness of the soft magnetic layer was 60 nm, the thickness of the intermediate layer was 10 nm, the thickness of the magnetic layer was 16 nm, the thickness of the metal protective layer was 5 nm, and the thickness of the mask layer was 33 nm.

Then, a SiO₂ resist was applied onto the mask layer by a spin coating method. The thickness of the SiO₂ resist was 60 nm. A glass stamp having the negative pattern of the magnetic recording pattern was pressed against the resist layer at a pressure of 1 MPa (about 8.8 kgf/cm²). Then, the stamp was separated from the resist layer and the magnetic recording pattern was transferred to the resist layer. In the magnetic recording pattern transferred to the resist layer, the convex portion of the resist had a circumferential shape with a width of 60 nm and the concave portion of the resist had a circumferential shape with a width of 40 nm. The thickness of the resist layer was 40 nm, and the thickness of the concave portion of the resist layer was about 10 nm. In addition, the angle of the concave portion of the resist layer with respect to the surface of the substrate was substantially 90 degrees.

Then, at the position of the concave portion of the resist layer, the mask layer was removed by dry etching and the magnetic layer was removed by ion beam etching. The dry etching was performed on the mask layer under the conditions of an O₂ gas flow rate of 40 sccm, a pressure of 0.3 Pa, a high-frequency plasma power of 300 W, a DC bias of 30 W, and an etching time of 30 seconds. In addition, the ion beam etching was performed under the conditions of an Ar gas flow rate of 10 sccm, a pressure of 0.1 Pa, an acceleration voltage of 300 V, and an etching time of 30 seconds.

The depth of the concave portion of the magnetic layer formed after the ion beam etching was about 10 nm. The holding force of the magnetic layer with a thickness of about 6 nm which remained in the concave portion of the magnetic layer was weaker than that of the convex portion of the magnetic layer by the injection of ions into the concave portion during the ion beam etching. In this way, the magnetic recording pattern which had a track width 60 of nm and included the convex portion and the concave portion was formed.

Then, a protective layer made of carbon was formed with a thickness of 5 nm by a CVD method. Finally, a lubricant layer, which was a fluorinated lubricant layer, was formed with a thickness of 2 nm. In this way, the manufacture of the discrete magnetic recording medium was completed.

### (Test of Magnetic Recording Medium)

First, a preliminary experiment for determining the width of the first signal used for a test was performed as follows.

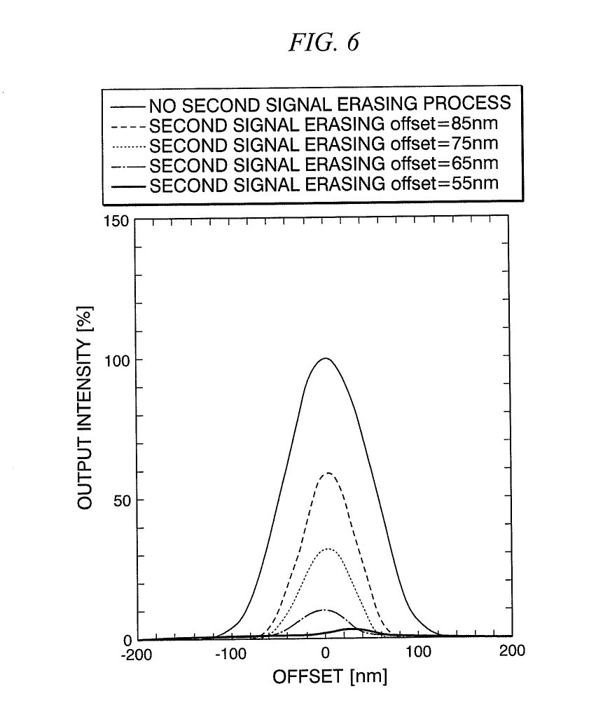

That is, a magnetic recording medium for a preliminary experiment was prepared which had the same laminated film as that of the above-mentioned magnetic recording medium and included a continuous magnetic layer without a magnetic recording pattern. A test head was used to write a 70-MHz signal as the second signal to the magnetic recording medium and measured the output intensity of the second signal. Then, the erasing signal for erasing the second signal was written with offsets of (distance) ±85 nm, ±75 nm, ±65 nm, and ±55 nm from the center of the written second signal in the radial direction. A 200-MHz signal was used as the erasing signal. Then, the output intensity of the second signal remaining after the erasing signal was written was measured. The measurement result is shown in FIG. 6.

FIG. 6 is a graph illustrating the distribution of the output intensity of the second signal in the vicinity of the center in the radial direction. Specifically, FIG. 6 is a graph illustrating the output intensity of the second signal remaining after the erasing signal is written when the output intensity of the second signal without an erasing signal written thereto is 100%. As shown in FIG. 6, as the offset is reduced, the output intensity of the remaining second signal is reduced. In addition, as can be seen from FIG. 6, when the offset is ±55 nm, the output intensity of the remaining second signal is insufficient and it is necessary to set the offset to ±65 nm or more in order to obtain sufficient output intensity after the erasing signal is written. Therefore, this proves that, in the test for the magnetic characteristics of the magnetic recording pattern, the signal with the smallest width used as the first signal with a width less than the track width is obtained by erasing the second signal with an offset of ±65 nm.

Then, the magnetic recording medium manufactured in this example was tested.

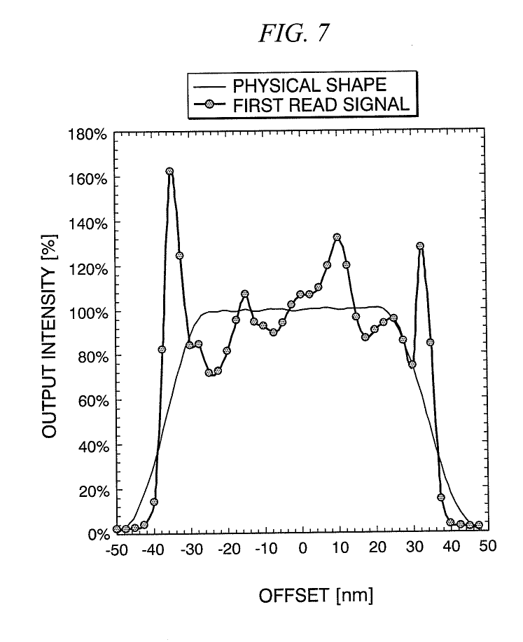

Specifically, the test was performed at an interval of 2.5 nm in the range of ±50 nm from the center of the track of the magnetic recording medium used for the test in the radial direction. That is, the writing head wrote the second signal at 70 MHz at the test position of the magnetic recording pattern, and the writing head wrote a 200-MHz erasing signal on both sides of the edge of the second signal in the track width direction with an offset of ±65 nm from the center of the second signal in the radial direction, thereby generating the first signal (signal frequency: 70 MHz). Whenever the first signal was generated, the reading head read the first signals and the output intensity of a plurality of first read signals corresponding to the measurement positions was measured. The measurement result is shown in FIG. 7.

FIG. 7 is a graph illustrating the distribution of the output intensity in the width direction of the track in the range of ±50 nm from the center in the radial direction. Specifically, FIG. 7 is a graph illustrating the output intensity when the output intensity at the center of the track in the radial direction in the distribution (a line with a physical shape in FIG. 7) of the output intensity, which is a target value in manufacturing, is 100%.

In the distribution of the output intensity in the width direction of the track shown in FIG. 7, the measurement result was substantially equal to the distribution (the line with a physical shape in FIG. 7), which is a target value in manufacturing, except that the output intensity was specifically high at both ends of the track in the width direction. In particularly, as shown in FIG. 7, in the magnetic recording medium manufactured in the example, it was confirmed that the output intensity of the region between the tracks was substantially 0 and the tracks were magnetically isolated from each other. This proved that, in the magnetic recording medium manufactured in the example, the manufacturing conditions of a magnetic layer patterning process were appropriate.

In the distribution of the output intensity in the width direction of the track shown in FIG. 7, the output intensity at both ends of the track in the width direction is more than 120% and the output intensity at both ends of the track in the width direction (a position with an offset of about ±35 nm in FIG. 7) is specifically higher than that of other portions. This proves that the magnetic recording medium test method according to this example can detect the position of the edge of the track in the width direction from the center in the radial direction with high sensitivity.

The inventors consider the reason why the output intensity of the edge of the track in the width direction is higher than that of other portions as follows.

That is, the signal recorded on the magnetic recording medium generates the magnetic field outside and has the demagnetizing field inside. For example, when it is considered that the signal recorded on the magnetic recording medium is formed by a small magnet, the demagnetizing field is generated inside the magnet and the demagnetizing field has the highest intensity at the center of the magnet (the boundary between the S-pole and the N-pole). In the magnetic recording medium according to this example, since the track shape is magnetically formed, the demagnetizing field is generated in the track. The intensity of the demagnetizing field in the track is the highest in the vicinity of the center of the track and is low at the edge of the track. Therefore, the inventors believe that, in the erasing signal writing process of erasing the second signal, the signal is likely to be erased in the vicinity of the center of the track by the influence of the demagnetizing field and the intensity of the generated first signal is low; and the signal is less likely to be erased at the edge of the track by the influence of the demagnetizing field and the intensity of the generated first signal at the edge of the track is higher than that of the first signal in the vicinity of the center of the track.

### INDUSTRIAL APPLICABILITY

The invention provides a magnetic recording medium test method which is suitable for testing the magnetic characteristic distribution of a discrete track medium and is capable of testing the magnetic characteristic distribution of a magnetic recording medium with high accuracy.

### REFERENCE SIGNS LIST

1: NON-MAGNETIC SUBSTRATE
2: MAGNETIC LAYER
5: MEASUREMENT POSITION
6: FIRST SIGNAL
9: PROTECTIVE LAYER
27: MAGNETIC HEAD
28: HEAD DRIVING UNIT
29: RECORDING/REPRODUCING SIGNAL SYSTEM
34: MEDIUM DRIVING UNIT
40: MAGNETIC RECORDING MEDIUM
41: DATA REGION
41a: MAGNETIC RECORDING PATTERN
42: SERVO INFORMATION REGION
43: BURST INFORMATION REGION
43a: BURST PATTERN
44: ADDRESS INFORMATION REGION
44a: ADDRESS PATTERN
45: PREAMBLE INFORMATION REGION
45a: PREAMBLE PATTERN
41b: CONVEX PORTION
41c: CONCAVE PORTION

1. A method of testing a magnetic recording medium including a magnetically isolated magnetic recording pattern on a non-magnetic substrate, comprising:
a first signal writing step of writing a first signal with a width less than a track width at a plurality of measurement positions on the magnetic recording pattern using a writing head;
a first signal reading step of reading the first signal using a reading head to obtain a plurality of first read signals corresponding to the measurement positions; and
an analysis step of analyzing magnetic characteristics of the magnetic recording pattern using the plurality of first read signals obtained in the first signal reading step.

2. The method of testing a magnetic recording medium according to claim 1,
wherein the first signal writing step includes:
a second signal writing step of writing a second signal with a width greater than that of the first signal to the magnetic recording pattern using the writing head; and
an erasing signal writing step of writing an erasing signal for erasing the second signal to one side or both sides of the edge of the second signal in a track width direction using the writing head, thereby generating the first signal.

3. The method of testing a magnetic recording medium according to claim 1,
wherein the magnetic recording pattern includes servo information, and
in the first signal writing step and the first signal reading step, the reading head reads the servo information and the magnetic head including the reading head and the writing head is located at a predetermined position on the magnetic recording pattern.

4. The method of testing a magnetic recording medium according to claim 1,
wherein the plurality of measurement positions are arranged on the magnetic recording pattern at intervals less than the track width in a radial direction of the non-magnetic substrate.

5. The method of testing a magnetic recording medium according to claim 1,
wherein, in the first signal reading step, the center of the reading head in the radial direction of the non-magnetic substrate is aligned with the center of the measurement position in the radial direction of the non-magnetic substrate, and the reading head reads the first signal.

6. A method of manufacturing a magnetic recording medium comprising the test method according to claim 1.
